(19) United States
(12) Patent Application Publication
(10) Pub. No.: US 2026/0032897 A1
(43) Pub. Date: Jan. 29, 2026

(54) SACRIFICIAL POLYSILICON AND ANNEAL FOR TRANSISTOR GATE STACK

(71) Applicant: Micron Technology, Inc., Boise, ID (US)

(72) Inventors: Huajie Chen, Boise, ID (US); Shivani Srivastava, Boise, ID (US); Tao Duy Nguyen, Boise, ID (US); Margit J. Johnson, Boise, ID (US); Karine Paulette Pierrette Florent, Boise, ID (US)

(21) Appl. No.: 19/278,272

(22) Filed: Jul. 23, 2025

Related U.S. Application Data
(60) Provisional application No. 63/674,925, filed on Jul. 24, 2024.

(51) Int. Cl. H10B 12/00

(52) U.S. Cl. CPC H10B 12/50; H10B 12/09

(57) ABSTRACT

A variety of applications can include a transistor with a reduced gate stack including a work function gate metal conditioned to achieve a desired effective work function of the gate stack, where the gate stack is structured without a polysilicon region. The effective work function can result from tuning in the fabrication process flow to achieve an effective work function approaching the effective work function of a gate stack of a transistor having a polysilicon region. The conditioned metal gate can result from forming polysilicon on the metal gate, annealing the polysilicon and metal gate, and removing the polysilicon. In an integrated process flow for forming such transistors in the periphery to a memory array region of a memory device, material for metal contact regions of the gate stacks of the transistors in the periphery can be used for metal digit lines to memory cells of the memory array region. Structuring a metal contact region having a metal contact directly on the gate metal without polysilicon can lower overlap capacitance and gate resistance, which can improve alternating current performance and operational speed of the memory device. An integration flow without polysilicon maintained in the gate stack can provide improved step height reduction of the periphery region versus the array region, which can provide improved yield and cost reduction.

### PRIORITY APPLICATION

This application claims the benefit of priority to U.S. Provisional Application Ser. No. 63/674,925, filed Jul. 24, 2024, which is incorporated herein by reference in its entirety.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a cross-sectional representation of features of an example transistor having a reduced gate stack, according to various embodiments.

FIG. 2 is a flow diagram of features of an example method of forming a memory device, according to various embodiments.

FIG. 3 is a flow diagram of features of an example method of forming a memory device, according to various embodiments.

FIGS. 4-9 illustrate an example process flow of integration of formation contacts to a memory array and formation of contacts to transistors in the periphery to the memory array using a sacrificial polysilicon layer, according to various embodiments.

FIG. 10 is a schematic of an example dynamic random-access memory device that can include an architecture having a memory array region and a periphery to the memory array region after common processing of metal digit lines in the memory array region and metal contacts in the periphery, according to various embodiments.

FIG. 11 is a block diagram illustrating an example of a machine upon which one or more embodiments of one or more memory components may be implemented, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Traditional process flows for memory devices, such as DRAMs, utilize the same metallization for complementary metal-oxide-semiconductor (CMOS) devices in the periphery to a memory array region and a memory array digit line in the memory array region. The same metallization, for example, can consist of barrier metals to a main conductor, where the barrier metals are designed for both CMOS devices in the periphery and the memory array. The same metallization used in traditional process flows for DRAMs in the periphery to a memory array and the memory array digit line can consist of, for example, metal barrier to a main conductor of tungsten (W), where the metal barrier includes titanium (Ti)/tungsten nitride (WN_{X})/tungsten silicide (WSi_{X}). With respect to the metal barrier, Ti can form a titanium silicide (TiSi_{X}) layer with an underlying polycrystalline silicon (polysilicon) on and contacting a gate metal and on which the Ti is deposited, while WN_{X} protects against Ti outdiffusion to the WSi_{X} and W layers. The WSi_{X} serves as a template for W to form low resistivity scaling. As DRAM scales to future designs, structural characteristics between array and periphery may no longer be the same.

A memory device, such as but not limited to a DRAM device, can use transistors in the periphery region to the memory array region of the memory devices, where the structural relationship of the transistors to the memory array region can affect operation of the memory device. Typically, CMOS technology for such transistors, implementing a conventional polysilicon gate and a silicon oxynitride (SiON) gate dielectric, uses doped polysilicon for work function (WF) control with the n-type transistor and the p-type transistor of the CMOS device doped separately. The work function corresponds to a minimum amount of energy needed to remove an electron from a solid to a point in a vacuum immediately outside the solid surface. With integration of fabrication processing of the memory array region and the periphery region of DRAM device, for example, the integration can be challenged due to step height difference between the memory array region and the periphery region.

In various embodiments, integrated processing of a memory array of a memory device with a periphery, such as a CMOS periphery, can be implemented with transistors formed in the periphery with metal gates, without polysilicon in a stack between the metal gate and a metal contact for the gate. The metal contact can contact the metal gate or the metal contact can contact a metal barrier region above and contacting the metal gate. The metal barrier region can be implemented by a single metal barrier region. A single metal barrier region is a region having one metal composition, which can include one or more metals and non-metals in a compound having metallic properties with respect to electrical conductivity. The metal barrier region can be implemented by multiple regions of metal compositions. Such an integrated processing, using CMOS technology, can include such transistors in the periphery realized with a high-k metal gate (HKMG).

A HKMG is a gate structure having a metal gate located on a high-k dielectric, where a high-k dielectric is a dielectric having a dielectric constant greater than that of silicon dioxide (3.7-3.9). Herein, a high-k dielectric is a dielectric having a dielectric constant greater than 3.9. The high-k dielectric in the HKMG can be located on a relatively thin layer of a nitrided silicon oxide (SiO_{X}N_{Y}) above a channel structure of a transistor. A gate located on a gate dielectric above a channel structure of a transistor along with the gate dielectric and a metal contact region on the gate can be referred to as a gate stack. A HKMG can provide a high performance CMOS device. A typical gate first integration can have a polysilicon layer on a HKMG followed by a metal contact to the polysilicon. Structuring a metal contact region having a metal contact directly on the gate metal or structuring a set of barrier metals with appropriate thickness on the gate metal of transistors in CMOS devices in the periphery to the memory array of a memory device can lower overlap capacitance and gate resistance, which can improve alternating current (AC) performance and operational speed of the memory device. Embodiments of an integration flow without polysilicon maintained in the gate stack can provide improved step height reduction, which can provide improved yield and cost reduction. Metals used in the memory array region and the periphery to the memory array region can be selected to lower unwanted capacitance and lower resistance of components for the memory device.

In various embodiments, a gate stack of a transistor is structured without a polysilicon region, while having a desired effective work function (eWF) within a specified range. In addition, the gate stack can be constructed with a reduced number of barrier metals in a metal contact region to a metal gate. Constructing the gate stack without a polysilicon region or without a polysilicon region and with a limited number of metal regions on a metal gate of the gate stack can reduce gate stack height, which can enhance the ability to increase device density in integrated electronic devices such as, but not limited to, memory devices. Conventional barrier metals such as titanium regions and tungsten nitride layered above a gate metal in transistors in a periphery to the memory array of a conventional memory device can be eliminated along with the use of a polysilicon region. Polysilicon elimination can reduce capacitance, reduce gate resistance, and reduce memory array to periphery stack height gap. However, polysilicon elimination can increase the eWF of the resultant gate stack. To compensate for increased eWF of a gate stack having such a removed layer/material design of these transistors in the memory array periphery, the metal gate of the reduced height gate stack can be a conditioned metal gate. The processing of the conditioned metal gate can include formation of a sacrificial polysilicon on the metal gate followed by an anneal and removal of the polysilicon, which can be used to control the eWF. The sacrificial polysilicon/anneal/sacrificial polysilicon removal technique can be used to provide an eWF that is approaches the value of a similar gate stack that includes polysilicon and the eliminated barrier metals. Optionally, a silane gas soak to form a thin region of silicon can be used in combination with the sacrificial polysilicon/anneal/sacrificial polysilicon removal technique to control the eWF. The thin region of silicon can be formed on the metal gate after the sacrificial polysilicon/anneal/sacrificial polysilicon removal is performed. Another option to control the eWF can include forming a thin material composition on the metal gate after the sacrificial polysilicon/anneal/sacrificial polysilicon removal is performed. The thin material composition can be, but is not limited to, titanium silicon nitride (Ti_{X}Si_{Y}N_{Z}). Another option to control the eWF of a gate stack can include performing a combination of formation of a thin material composition and a silane soak after the sacrificial polysilicon/anneal/sacrificial polysilicon removal procedure.

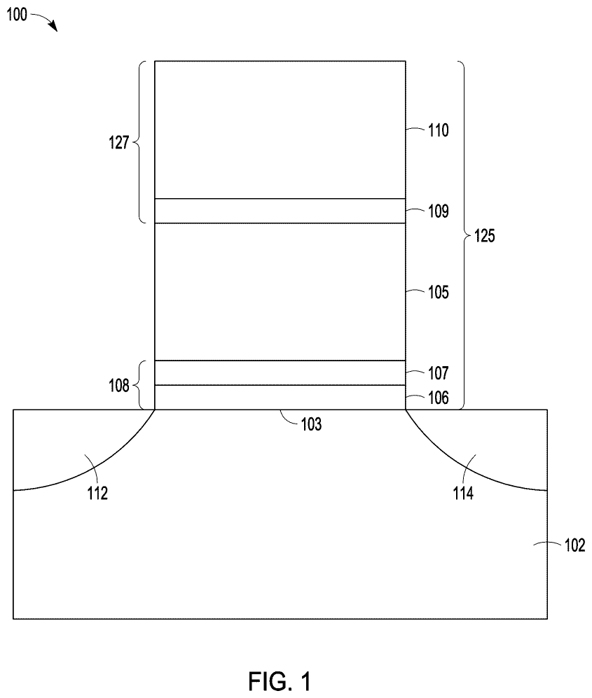

FIG. 1 is a cross-sectional representation of features of an embodiment of an example transistor 100 having a reduced gate stack. Transistor 100 can include a gate stack 125 on and contacting a channel structure 103 in a substrate 102, where channel structure 103 separates source/drain regions 112 and 114. Gate stack 125 can include a gate dielectric 108 on channel structure 103, a metal gate 105 on and contacting gate dielectric 108, and a metal contact region 127 on and contacting metal gate 105. Metal gate 105 can be a doped metal gate. Gate dielectric 108 can be a multilayer gate dielectric positioned between and contacting gate stack 125 and channel structure 103. Gate dielectric 108 have a high-k dielectric 107 on an interlayer dielectric (ILD) 106. High-k dielectric 107 can include, but is not limited to, hafnium oxide (HfO_{X}), zirconium oxide (ZrO_{X}), aluminum oxide (AlO_{X}), titanium oxide (TiO_{X}), gadolinium oxide (GaO_{X}), niobium oxide (NbO_{X}), tantalum oxide (TaO_{X}), combinations thereof, or mixtures thereof. ILD 106 can be, but is not limited to, a SiO_{X} region between and contacting high-k dielectric 107 and channel structure 103. Other materials can be used in construction of the multilayer gate dielectric. With gate dielectric 108 including a high-k dielectric, the combination of metal gate 105 and gate dielectric provides a HKMG. Gate stack 125 can be structured without a polysilicon region in gate stack 125. Metal contact region 127 can include an inner metal region 109 and an outer metal region 110. Metal contact region 127 is not limited to a two layer structure. Gate stack 125 can have a height of 400 angstroms or less, extending from the surface of channel structure 103 at which gate dielectric 108 contacts channel structure 103.

Typically, a gate stack of a transistor without a polysilicon region will have an eWF larger than the eWF of a similarly arranged transistor that has a polysilicon region. The amount of increase in eWF can depend on where the transistor is a n-channel metal oxide semiconductor (NMOS) transistor or p-channel metal oxide semiconductor (PMOS) transistor. Transistor 100 can be conditioned having gate stack 125 structured with an eWF that approaches the eWF of the similar transistor having a polysilicon region. Transistor 100 can be conditioned by conditioning metal gate resulting from depositing polysilicon on the metal gate, annealing the polysilicon and metal gate, and removing the polysilicon. The deposited polysilicon can be doped or undoped polysilicon. The annealing can be performed at or above a threshold temperature range to achieve a desired eWF. The threshold temperature range can include a temperature spike above 800° C. A temperature spike of 1050° C. can be used depending on the desired eWF, the nature of the polysilicon, and gate stack components. The annealing can be conducted by rapid thermal processing (RTP). The annealing of the polysilicon can provide for diffusion of silicon or dopants in the polysilicon into metal gate 105 and/or gate dielectric 108. Dopants in the polysilicon can include, but are not limited to, phosphorus.

Variations of transistor 100 or transistors similar to transistor 100 can include a number of different embodiments that may be combined depending on the application of such transistors or the architecture or process flow of an integrated circuit for which such transistors are implemented. Such variations of transistor 100 can include transistor 100 being a transistor of a CMOS device. Metal gate 105 can include titanium nitride (TiN_{X}). Other metals can be used for metal gate 105. Metal gate 105 can be a WF gate metal. For transistor 100 being a NMOS transistor, metal gate 105 can be a WF gate metal including lanthanum (La) and TiN_{X} with La on the bottom of the combination on and contacting dielectric 108 and TiN_{X} on top of the La, where the La can be a few Å thick. For transistor 100 being a PMOS transistor, metal gate 105 can be a WF gate metal including TiN_{X}, aluminum (Al), and TiN_{X} with TiN_{X} on the bottom of the combination on and contacting dielectric 108, Al on the bottom TiN_{X}, and TiN_{X} on top of the Al. Optionally, for the PMOS transistor, the use of Al may be skipped, providing a single TiN_{X}. The PMOS metal gate may have the NMOS metal gate unetched on top. During high temperature anneals, the La in the NMOS transistor and the Al in the PMOS transistor can diffuse to the dielectric 108 and form a dipole layer (typically at the interface of high-k dielectric 107 and ILD 106), which causes WF shift to another value for the WF gate metal.

Metal contact region 127 can include a WSi_{X} region as inner metal region 109 on and contacting metal gate 105 and a W region as outer metal region 110 on the WSi_{X} region. In an example of transistor 100, an outer metal region 110 of W can have, but is not limited to, vertical thickness of about 140 Å and an inner metal region 109 of WSi_{X} can have, but is not limited to, a vertical thickness of about of about 30 Å. Other vertical thicknesses (or heights) of outer metal region 110 and inner metal region 109 can be implemented.

Variations of transistor 100 or transistors similar to transistor 100 can include the transistor being a NMOS transistor with a gate stack, without a polysilicon region, having an effective work function of 4.4 eV or less. Variations can include the transistor being a PMOS transistor with a gate stack, without a polysilicon region, having an effective work function of 4.85 eV or less.

Transistor 100 can be used in a variety of applications. Transistor 100 can be structured in a periphery to a memory array region of a memory device, providing a reduced gate stack relative to the memory array region. The reduced gate stack can provide a smaller step between the gate stack and memory array region, where material formation of the metal contact region of the gate stack and material formation of a contact to one or memory cells can be the same material that is formed in a common integrated procedure.

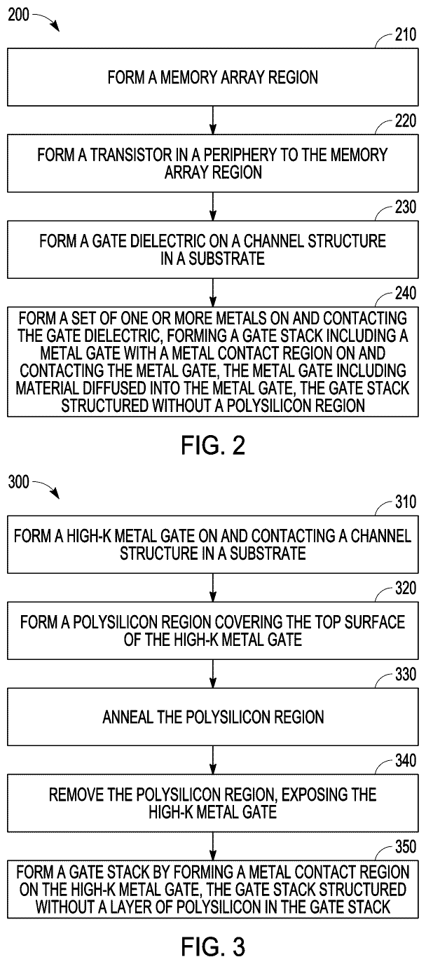

FIG. 2 is a flow diagram of features of an embodiment of an example method 200 of forming a memory device. At 210, a memory array region is formed. At 220, a transistor is formed in a periphery to the memory array region. The transistor can be a transistor of a CMOS device in the periphery to an array of memory cells of the memory array region. The transistor in the periphery can be part of the circuitry for interfacing with and maintaining status of the memory cells of the memory array. The transistor can be formed while processing components in the memory array region.

At 230, in forming the transistor, a gate dielectric is formed on a channel structure in a substrate for the memory device. The gate dielectric can be implemented in various formats. The formed gate dielectric can be a high-k dielectric material on an ILD, with the ILD on and contacting the channel structure and the high-k dielectric material to contact a metal gate. The high-k dielectric can be, but is not limited to, HfO_{X}, ZrO_{X}, AlOₓ, TiO_{X}, GaOₓ, NbOₓ, TaO_{X}, combinations thereof, or mixtures thereof. The ILD can be SiO_{X} or other non-high-k dielectric.

At 240, a set of one or more metals is formed on and contacting the gate dielectric, forming a gate stack. The gate stack can include a metal gate with a metal contact region on and contacting the metal gate, where the metal gate can include material diffused into the metal gate and the gate stack can be structured without a polysilicon region. The gate stack can have a height extending from the channel structure, where the height is 400 angstroms or less. With the gate dielectric being a high-k dielectric or a high-k dielectric on an ILD, structure of the metal gate on such a gate dielectric provides a HKMG.

Variations of method 200 or methods similar to method 200 can include a number of different embodiments that may be combined depending on the application of such methods or the architecture or process flow of an integrated circuit for which such methods are implemented. Such methods can include forming the metal gate to include TiN_{X}. The metal gate can be a work function metal other than TiN_{X}. Variations can include forming the metal contact region with two regions. For example, the metal contact region can include a WSi_{X} region on and contacting a TiN_{X} metal gate, and a W region on the WSi_{X} region. In an example, such a W region can have a height of about 140 Å and such a WSi_{X} can have a height of about 30 Å. With the transistor being a p-channel metal oxide semiconductor (PMOS) transistor, the gate stack, without a polysilicon region, can have a height of 400 angstroms or less extending from the channel structure. With the transistor being a n-channel metal oxide semiconductor (NMOS) transistor, the gate stack, without a polysilicon region, can have a height of 350 nm or less extending from the channel structure.

Formation of the gate stack can include a number of variations. The metal gate of the gate stack can be conditioned by depositing polysilicon on the metal gate, annealing the polysilicon and metal gate at a threshold temperature to achieve a reduced effective work function for the gate stack, and removing the polysilicon. The threshold temperature can include a temperature spike above 800° C., for example, but not limited to, a spike temperature of 1050° C. The annealing can be conducted by RTP. Features of method 200 can be utilized in the formation of transistor 100 of FIG. 1. The formation of a transistor in the manner as performed in method 200 of forming a memory device or variations of method 200 can be performed in formation of other electronic devices. Optionally, a silane gas soak to form a thin region of silicon can be used in combination with the sacrificial polysilicon/anneal/sacrificial polysilicon removal technique to control the eWF, with the silane soak performed after the sacrificial polysilicon/anneal/sacrificial polysilicon removal is performed. The silane soak can provide a mechanism to deposit the thin region of Si to have thickness in the range of approximately 0.5 nm to 3 nm, which can typically be a range of 0.5 nm to 1 nm. Another option to control the eWF can include forming a thin material composition on the metal gate after the sacrificial polysilicon/anneal/sacrificial polysilicon removal is performed. The thin material composition can be, but is not limited to, Ti_{X}Si_{Y}N_{Z} that can be deposited in a chemical vapor deposition (CVD) process. The thin material composition can have a thickness in the range of approximately 1 nm to 5 nm, which can typically be a range of 3 nm to 4 nm. Another option to control the eWF of the gate stack can include performing a combination of formation of a thin material composition and a silane soak after the sacrificial polysilicon/anneal/sacrificial polysilicon removal procedure.

FIG. 3 is a flow diagram of features of an embodiment of an example method 300 of forming a memory device. At 310, a HKMG is formed on and contacting a channel structure in a substrate. The HKMG is formed for a transistor in a periphery to a memory array region of the memory device. Forming the HKMG can include forming a WF gate metal. The HKMG can include TiN_{X} on a dielectric including, but not limited to, HfO_{X}, ZrO_{X}, AlOₓ, TiO_{X}, GaOₓ, NbOₓ, TaO_{X}, combinations thereof, or mixtures thereof on a SiOₓ or other non-high-k dielectric. The HKMG can include La doped in the TiN_{X} to provide the WF gate metal. Metals other than La can be used.

At 320, a polysilicon region is formed covering the top surface of the HKMG. At 330, the polysilicon region is annealed. The polysilicon can be annealed at a threshold temperature range to achieve a selected effective work function for the gate stack being formed within a specified range. The threshold temperature range can include a temperature spike above 800° C. For example, the threshold temperature range can include, but is not limited to, a spike temperature of 1050° C. The anneal can be performed by a RTP procedure.

At 340, the polysilicon region is removed, exposing the HKMG. At 350, a gate stack is formed by forming a metal contact region on the HKMG, where the gate stack is structured without a layer of polysilicon in the gate stack. The gate stack includes the metal contact region and the HKMG.

Variations of method 300 or methods similar to method 300 can include a number of different embodiments that may be combined depending on the application of such methods or the architecture or process flow of an integrated circuit for which such methods are implemented. Such methods can include forming the HKMG on and contacting an ILD positioned over memory cells in the memory array region, while forming the HKMG for the transistor in the periphery to the memory array region, and forming the polysilicon region covering the HKMG in the memory array region, while forming the polysilicon region covering the top surface of the HKMG in the periphery. Variations can include forming an oxide on the polysilicon region in the memory array region and the periphery. The oxide, polysilicon region, and the HKMG can be selectively removed from the memory array region, while substantially maintaining the oxide, the polysilicon region, and the HKMG in the periphery. A contact to a memory cell can be formed, while maintaining the polysilicon region above the HKMG. Variations can include, after removing the polysilicon region from the HKMG in the periphery, forming the metal contact region on the contact to the memory cell and on the ILD in the memory array region while forming the metal contact region on the HKMG for the transistor in the periphery. The metal contact region can be formed as multiple regions of different materials. Variations can include forming the metal contact region by forming a WSi_{X} region on and contacting the HKMG and forming a W region on the WSi_{X} region.

Optionally, a silane gas soak to form a thin region of silicon on the HKMG can be used in combination with the sacrificial polysilicon/anneal/sacrificial polysilicon removal technique to control the eWF, where forming the thin region of silicon on the HKMG is performed after the sacrificial polysilicon/anneal/sacrificial polysilicon removal is performed. The silane soak can provide a mechanism to deposit the thin region of Si to have thickness in the range of approximately 0.5 nm to 3 nm, which can typically be a range of 0.5 nm to 1 nm. Another option to control the eWF can include forming a thin material composition on the HKMG after the sacrificial polysilicon/anneal/sacrificial polysilicon removal is performed. The thin material composition can be, but is not limited to, Ti_{X}Si_{Y}N_{Z} that can be deposited in a CVD process. The thin material composition can have a thickness in the range of approximately 1 nm to 5 nm, which can typically be a range of 3 nm to 4 nm. Another option to control the eWF of a gate stack can include performing a combination of formation of a thin material composition and a silane soak after the sacrificial polysilicon/anneal/sacrificial polysilicon removal procedure.

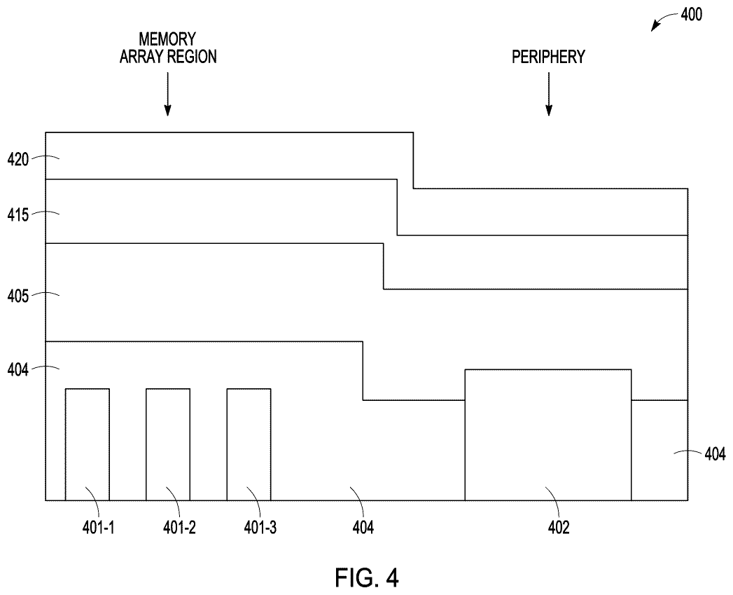

FIGS. 4-9 illustrate an embodiment of an example process flow of integration of formation contacts to a memory array and formation of contacts to transistors in the periphery to the memory array using a sacrificial polysilicon layer. Processing the sacrificial polysilicon can be used to condition the periphery transistors of the integrated process flow to achieve a desired eWF of the gate stacks of the transistors.

FIG. 4 illustrates a cross-sectional view of a structure 400, having a memory array region and a periphery, as an intermediate structure in forming a memory device. An ILD 404 placed on and between silicon regions 402-1, 401-2, and 401-3 has been formed in the memory array region. Though three silicon regions are shown, more or fewer than three silicon regions can be formed. For a memory array region, such silicon regions can be significantly more in number than three. ILD 404 can include SiO_{X}, such as SiO₂, silicon nitride, such as Si₃N₄, or other appropriate dielectric material. The memory array region can include a HKMG region 405 on ILD 404, where HKMG region 405 extends horizontally from the periphery. The periphery includes HKMG region 405 formed on substrate region 402, which can be a silicon substrate region for a PMOS transistor or for a NMOS transistor, and on ILD 404 in the periphery. ILD 404 is different from ILD 206 in FIG. 1. For a PMOS transistor in the periphery, substrate region 402 can include a silicon germanium (SiGe) region for the PMOS transistor. HKMG region can include, but is not limited to, a TiN_{X} metal gate or other WF metal gate on a high-k dielectric that is on a ILD for a gate dielectric.

An oxide region 420 has been formed on a sacrificial polysilicon 415 that has been formed on HKMG region 405 in both the memory array region and in the periphery. The formation of polysilicon 415 and oxide region 420 can be achieved using a deposition process for the particular polysilicon and oxide being formed to provide protection to HKMG region 405 in the periphery during memory array processing in the memory array region. An anneal can be applied to structure 400 post-formation of sacrificial polysilicon 415 and oxide region 420 for diffusion of polysilicon and/or dopants of polysilicon 415 into the metal gate of HKMG region 405. Dopants in the polysilicon can include, but are not limited to, phosphorus. The annealing can be performed at or above a threshold temperature range to achieve a desired eWF. The threshold temperature range can include a temperature spike above 800° C. A temperature spike of 1050° C. can be used, depending on the desired eWF, the nature of the polysilicon, and gate stack components. The annealing can be conducted by RTP.

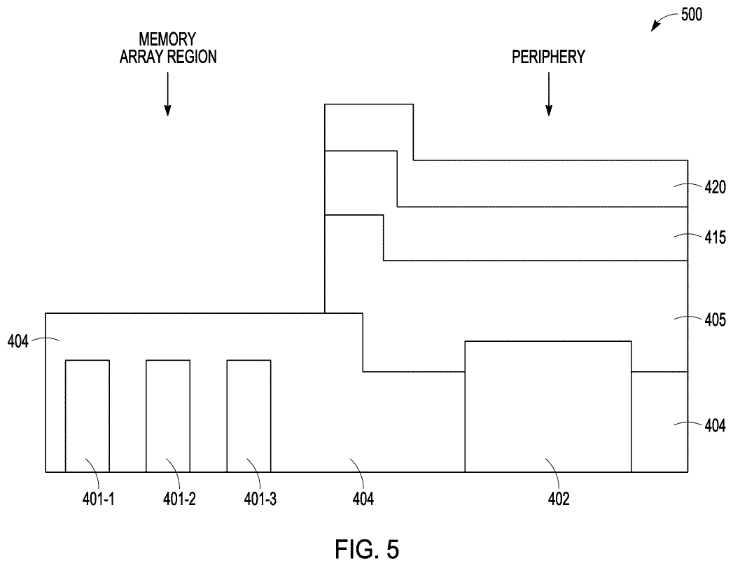

FIG. 5 illustrates a cross-sectional view of a structure 500, having a memory array region and a periphery, after processing structure 400 of FIG. 4. HKMG 405, sacrificial polysilicon 415 and oxide region 420 have been removed in the memory array region, exposing a top surface of ILD 404. The removal in the memory array region can be conducted by an etching process. The removal process may reduce the thickness of oxide region 420 in the periphery. Such a process may use masking materials to selectively remove HKMG 405, sacrificial polysilicon 415 and oxide region 420 from the memory array region while maintaining HKMG 405, sacrificial polysilicon 415 and at least a reduced oxide region 420 in the periphery.

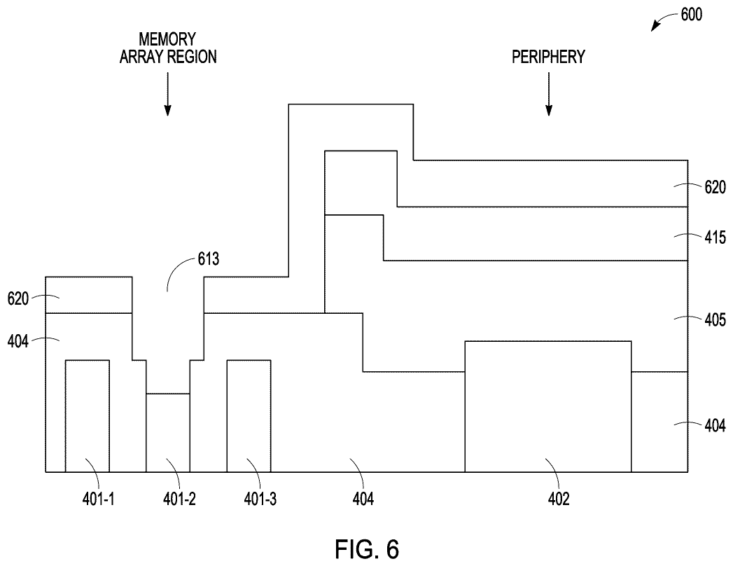

FIG. 6 illustrates a cross-sectional view of a structure 600, having a memory array region and a periphery, after processing structure 500 of FIG. 5. Processing to provide a contact to a memory cell of silicon region 401-2 has been performed. Additional oxide 620 has been formed in the memory array region on ILD 404 and the periphery, changing oxide region 420 in the periphery to oxide 620. An opening 613 through oxide 620 and ILD 404 has been formed over silicon region 401-2, including removing a portion of silicon region 401-2, recessing silicon region 401-2.

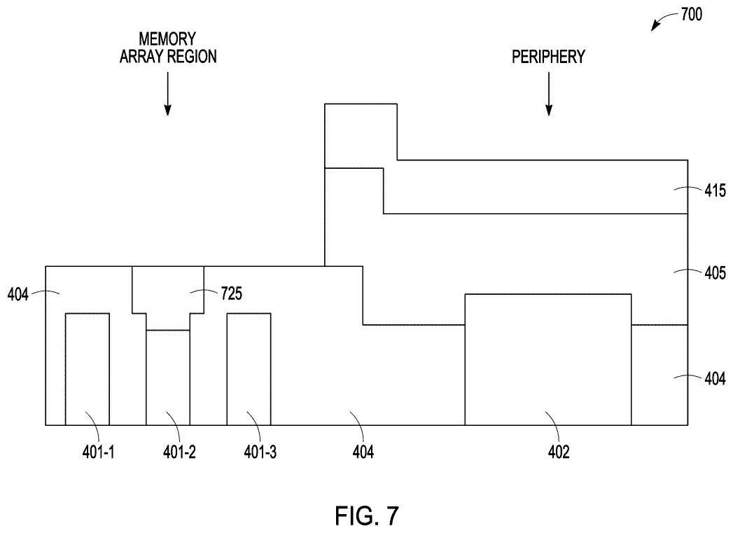

FIG. 7 illustrates a cross-sectional view of a structure 700, having a memory array region and a periphery, after processing structure 600 of FIG. 6. Metal 725 has been formed in opening 613 over silicon region 401-2 of FIG. 6 and oxide 620 has been removed from the memory array region and from the periphery. Metal 725 can be deposited by a deposition process appropriate for selected metal 725. Metal 725 can have a single metal format, a mixture of metals, or a layered format of multiple metals. Metal 725 can be, but is not limited to, Ti, TiN, or a combination of Ti and TiN.

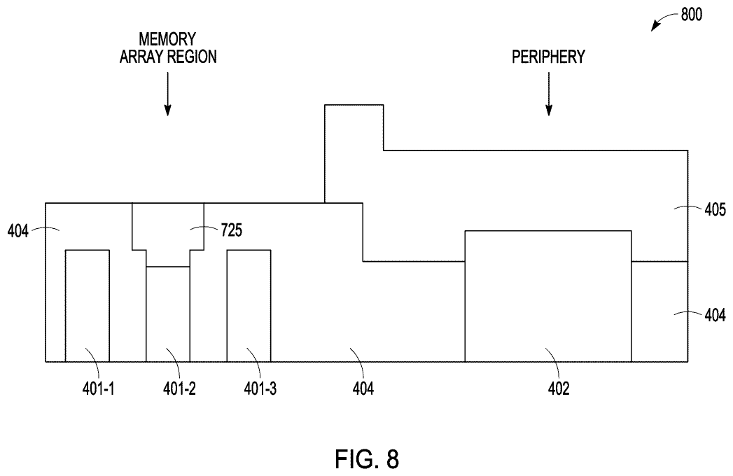

FIG. 8 illustrates a cross-sectional view of a structure 800, having a memory array region and a periphery, after processing structure 700 of FIG. 7. Sacrificial polysilicon 415 has been removed from the periphery, exposing the surface of HKMG region 405 in the periphery.

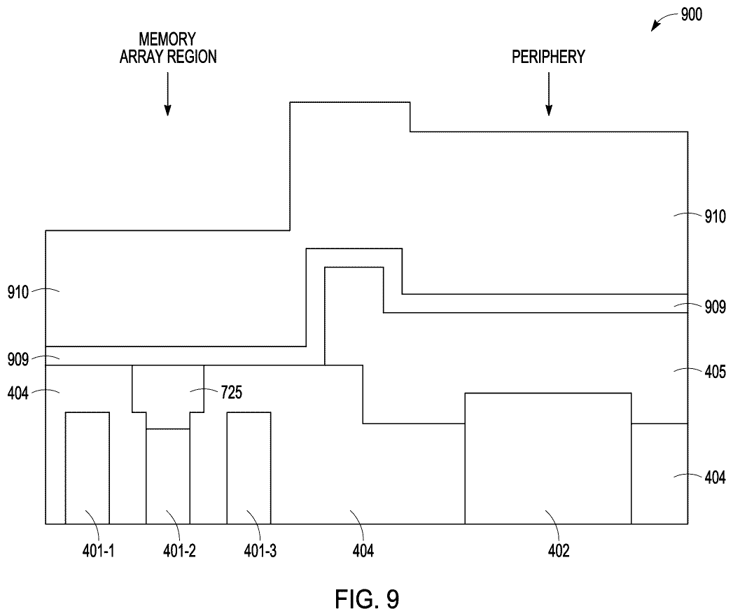

FIG. 9 illustrates a cross-sectional view of a structure 900, having a memory array region and a periphery, after processing structure 800 of FIG. 8. A metal contact region has been formed on HKMG region 405 in the periphery and a digit line has been formed on metal 725 on silicon region 401-2 and on ILD 404 in the memory array region. The metal contact region can be formed of the same metals as the digit line in a common procedure. The metal contact region has been formed having a metal barrier region 909 on HKMG region 405 with metal contact 910 on metal barrier region 909 in the periphery, and the digit line has been formed having metal barrier region 909 on metal 725 on silicon region 401-2 and on ILD 404 in the memory array region with metal contact 910 on metal barrier region 909 in the memory array region. Metal barrier region 909 can be, but is not limited to, WSi_{X} and metal contact 910 can be, but is not limited to, W.

Various deposition techniques for components of structures 400-900 in the process flow of FIGS. 4-9 can be used that are typical for the material being formed, the dimensions of the material being formed, and the architecture in which the material is being formed. Selective etching can be used to remove selected regions in the processing discussed with respect to FIGS. 4-9. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in removal of selected regions in connecting digit lines to digit line contacts in the memory array.

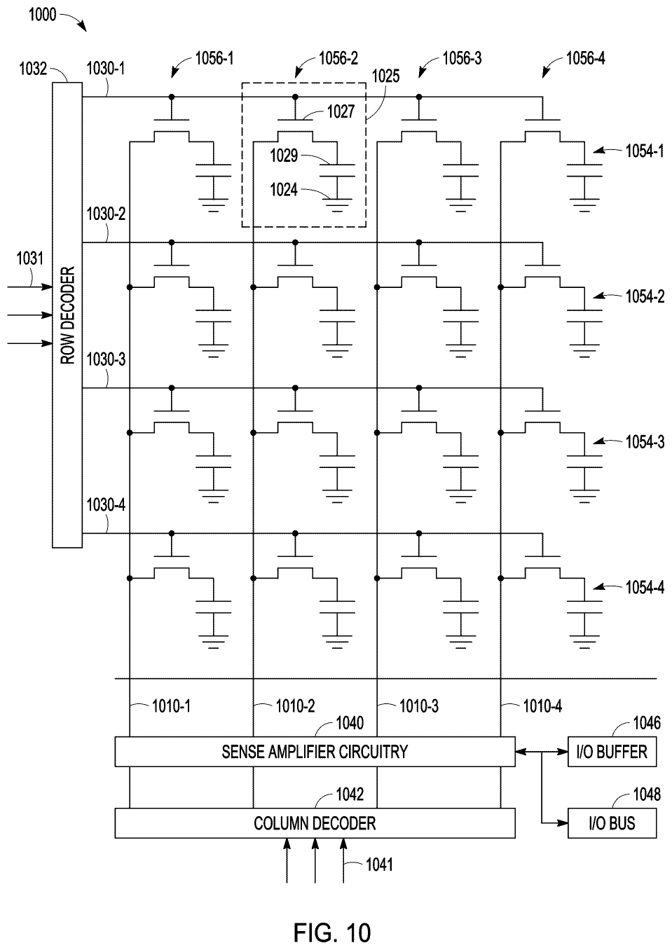

FIG. 10 is a schematic of an embodiment of an example DRAM device 1000 that can include an architecture having a memory array region and a periphery to the memory array region after common processing of metal digit lines in the memory array region and metal contacts in the periphery, without polysilicon structured on a transistor gate to connect to a metal contact for the transistor in the periphery, as taught herein. DRAM device 1000 can include an array of memory cells 1025 (only one being labeled in FIG. 10 for case of presentation) arranged in rows 1054-1, 1054-2, 1054-3, and 1054-4 and columns 1056-1, 1056-2, 1056-3, and 1056-4. For simplicity and case of discussion, the array is shown in only two dimensions, but the array can be extended into the third dimension. Further, while only four rows 1054-1, 1054-2, 1054-3, and 1054-4 and four columns 1056-1, 1056-2, 1056-3, and 1056-4 of four memory cells are illustrated, DRAM devices like DRAM device 1000 can have significantly more memory cells 1025 (e.g., tens, hundreds, or thousands of memory cells) per row or per column.

Each memory cell 1025 can include a single transistor 1027 and a single capacitor 1029, which is commonly referred to as a ITIC (one-transistor-one capacitor cell). One plate of capacitor 1029, which can be termed the “node plate,” is connected to the drain terminal of transistor 1027, whereas the other plate of the capacitor 1029 is connected to a reference 1024, which can be ground. Each capacitor 1029 within the array of ITIC memory cells 1025 typically serves to store one bit of data, and the respective transistor 1027 serves as an access device to write to or read from storage capacitor 1029.

The transistor gate terminals within each row of rows 1054-1, 1054-2, 1054-3, and 1054-4 are portions of respective access lines 1030-1, 1030-2, 1030-3, and 1030-4 (for example, word lines), and the transistor source terminals within each of columns 1056-1, 1056-2, 1056-3, and 1056-4 are electrically connected to respective digit lines 1010-1, 1010-2, 1010-3, and 1010-4 (for example bit lines). A row decoder 1032 can selectively drive the individual access lines 1030-1, 1030-2, 1030-3, and 1030-4, responsive to row address signals 1031 input to row decoder 1032. Driving a given access line at a high voltage causes the access transistors within the respective row to conduct, thereby connecting the storage capacitors within the row to the respective digit lines, such that charge can be transferred between the digit lines and the storage capacitors for read or write operations. Both read and write operations can be performed via sense amplifier circuitry 1040, which can transfer bit values between the memory cells 1025 of the selected row of the rows 1054-1, 1054-2, 1054-3, and 1054-4 and input/output buffers 1046 (for write/read operations) or external input/output data buses 1048.

A column decoder 1042 responsive to column address signals 1041 can select which of the memory cells 1025 within the selected row is read out or written to. Alternatively, for read operations, the storage capacitors 1029 within the selected row may be read out simultaneously and latched, and the column decoder 1042 can then select which latch bits to connect to the output data bus 1048. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

Digit lines 1010-1, 1010-2, 1010-3, and 1010-4 can be constructed as metal digit lines in a process flow with a metal contact to a device or circuit in the periphery, as taught herein, that can include sense amplifier circuitry 1040. The metal can be the same for digit lines 1010-1, 1010-2, 1010-3, and 1010-4 and the metal contact and can be formed at the same time in the fabrication process flow. Digit lines 1010-1, 1010-2, 1010-3, and 1010-4 can be structured with at most one metal barrier to each respective digit line contact for digit lines 1010-1, 1010-2, 1010-3, and 1010-4, while the associated metal contacts in the periphery can be structured with at most one metal barrier to corresponding gates of the transistors in the periphery, where the metal contacts are connected to the gates without polysilicon located in the stack between the metal contacts and the gates. In other embodiments, digit lines 1010-1, 1010-2, 1010-3, and 1010-4 can be structured with multiple metal barriers to each respective digit line contact for digit lines 1010-1, 1010-2, 1010-3, and 1010-4, while the associated metal contacts in the periphery can be structured with multiple metal barriers to corresponding gates of the transistors in the periphery, where the metal contacts are connected to the gates without polysilicon located in the stack between the metal contacts and the gates, where the gates have been conditioned to achieve an eWF within a specified range. In various embodiments, digit lines 1010-1, 1010-2, 1010-3, and 1010-4 contact digit line contacts and the metal contacts in the periphery contact gates of transistors. Variations can include the number of metal barriers in the periphery being larger than the number of metal barriers to gates in the memory array region. Alternatively, the number of metal barriers in the memory array can be larger than the number of metal barriers to gates in the periphery. Reduction of unwanted capacitance in the memory array region can include limiting the thickness of metal barriers as a unit between digit lines and digit line contacts in the memory array region.

DRAM device 1000 may be implemented as an integrated circuit within a package that includes pins for receiving supply voltages (e.g., to provide the source and gate voltages for the transistors 1027) and signals (including data, address, and control signals). FIG. 10 depicts DRAM device 1000 in simplified form to illustrate basic structural components, omitting many details of the memory cells 1025 and associated access lines 1030-1, 1030-2, 1030-3, and 1030-4 and digit lines 1010-1, 1010-2, 1010-3, and 1010-4 as well as the peripheral circuitry. For example, in addition to the row decoder 1032 and column decoder 1042, sense amplifier circuitry 1040, and buffers 1046, DRAM device 1000 may include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 1054-1, 1054-2, 1054-3, and 1054-4 and columns 1056-1, 1056-2, 1056-3, and 1056-4 of memory cells 1025 can be arranged along a single horizontal plane (i.e., a plane parallel to the layers) of the semiconductor substrate, e.g., in a rectangular lattice with mutually perpendicular horizontal access lines 1030-1, 1030-2, 1030-3, and 1030-4 and digit lines 1010-1, 1010-2, 1010-3, and 1010-4. In 3D DRAM arrays, the memory cells 1025 can be arranged in a 3D lattice that encompasses multiple vertically stacked horizontal planes corresponding to multiple device tiers of a multi-tier substrate assembly, with each device tier including multiple parallel rows of memory cells 1025 whose transistor gate terminals are connected by horizontal access lines such as access lines 1030-1, 1030-2, 1030-3, and 1030-4. A “device tier,” as used herein, may include multiple layers (or levels) of materials, but forms the components of memory devices of a single horizontal tier of memory cells. Digit lines 1010-1, 1010-2, 1010-3, and 1010-4 can extend vertically through all or at least a vertical portion of the multi-tier structure, and each of the digit lines 1010-1, 1010-2, 1010-3, and 1010-4 can connect to the transistor source terminals of respective vertical columns 1056-1, 1056-2, 1056-3, and 1056-4 of associated memory cells 1025 at the multiple device tiers. Such a 3D configuration of memory cells enables further increases in bit density compared with 2D arrays.

Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

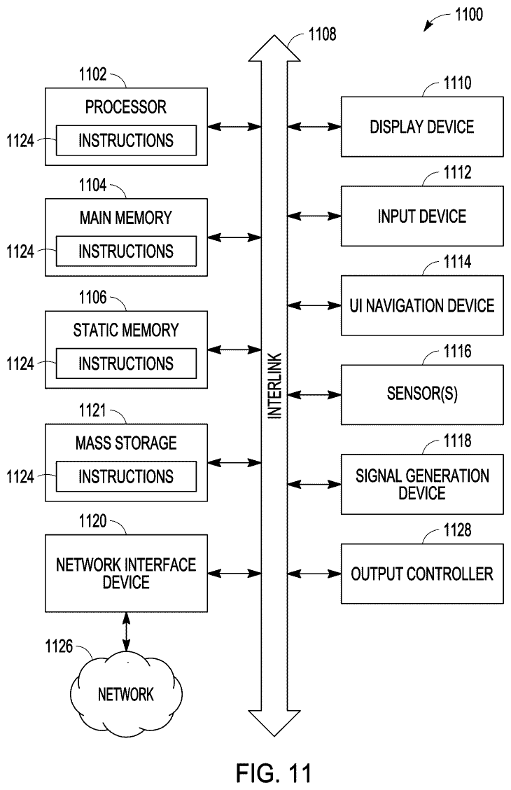

FIG. 11 illustrates a block diagram of an example machine 1100 having one or more embodiments of memory components discussed herein. In alternative embodiments, machine 1100 may operate as a standalone device or may be connected (e.g., networked) to other machines. In a networked deployment, machine 1100 may operate in the capacity of a server machine, a client machine, or both in server-client network environments. In an example, machine 1100 may act as a peer machine in peer-to-peer (P2P) (or other distributed) network environment. Machine 1100 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 1100 can include one or more memory devices having structures as discussed with respect to transistor 100 of FIG. 1 or structure 900 of FIG. 9.

Machine (e.g., computer system) 1100 may include a hardware processor 1102 (e.g., a CPU, a GPU, a hardware processor core, or any combination thereof), a main memory 1104 and a static memory 1106, some or all of which may communicate with each other via an interlink (e.g., bus) 1108. Machine 1100 may further include a display unit 1110, an alphanumeric input device 1112 (e.g., a keyboard), and a user interface (UI) navigation device 1114 (e.g., a mouse). In an example, display unit 1110, alphanumeric input device 1112, and UI navigation device 1114 may be a touch screen display. Machine 1100 may additionally include a mass storage (e.g., drive unit) 1121, a signal generation device 1118 (e.g., a speaker), a network interface device 1120, and one or more sensors 1116, such as a global positioning system (GPS) sensor, compass, accelerometer, or other sensor. Machine 1100 may include an output controller 1128, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 1100 may include a machine-readable medium on which is stored one or more sets of data structures or instructions 1124 (for example, software or microcode) embodying or utilized by machine 1100. Instructions 1124 may also reside, completely or at least partially, within main memory 1104, within static memory 1106, within mass storage 1121, or within hardware processor 1102 during execution thereof by machine 1100. In an example, one or any combination of hardware processor 1102, main memory 1104, static memory 1106, or mass storage 1121 may constitute machine-readable medium. Machine-readable medium can be a single medium or multiple media (e.g., a centralized or distributed database, or associated caches and servers) configured to store one or more instructions 1124.

The term “machine-readable medium” may include any medium that is capable of storing instructions for execution by machine 1100 and that cause machine 1100 to perform any one or more of the techniques for which machine 1100 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 1124 (e.g., software, programs, microcode, an operating system (OS), etc.) or other data stored on mass storage 1121, can be accessed by memory 1104 for use by processor 1102. Memory 1104 (e.g., DRAM) is typically fast, but volatile, and thus a different type of storage than mass storage 1121 (e.g., an SSD), which is suitable for long-term storage, including while in an “off” condition. Instructions 1124 or data in use by a user or machine 1100 are typically loaded in memory 1104 for use by processor 1102. When memory 1104 is full, virtual space from mass storage 1121 can be allocated to supplement memory 1104; however, because mass storage 1121 is typically slower than memory 1104, and write speeds are typically at least twice as slow as read speeds, use of virtual memory can greatly reduce user experience due to storage device latency (in contrast to memory 1104, e.g., DRAM). Further, use of mass storage 1121 for virtual memory can greatly reduce the usable lifespan of mass storage 1121.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 1124 may further be transmitted or received over a communications network 1126 using a transmission medium via network interface device 1120 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 1120 may include one or more physical jacks (e.g., Ethernet, coaxial, or phone jacks) or one or more antennas to connect to the communications network 1126. In an example, network interface device 1120 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 1100 or data to or from machine 1100. The transportation can include using digital or analog communications signals that can be transmitted over the transmission medium to facilitate communication of such software or data.

The following are example embodiments of devices and methods, in accordance with the teachings herein.

An example memory device 1 can comprise a memory array region and a transistor in a periphery to the memory array region. The transistor can include a gate dielectric on a channel structure in a substrate and a set of metals on and contacting the gate dielectric, forming a gate stack. The gate stack can include a metal gate with a metal contact region on and contacting the metal gate, where the gate stack is structured without a polysilicon region. The metal gate or the gate dielectric including material diffused into the metal gate and/or the gate dielectric.

An example memory device 2 can include features of example memory device 1 and can include the gate dielectric to include a high-k dielectric material.

An example memory device 3 can include features of example memory device 2 and any of the preceding example memory devices and can include the gate dielectric including a SiO_{X} or SiO_{X}N_{Y} region between and contacting the gate stack and the channel structure.

An example memory device 4 can include features of any of the preceding example memory devices and can include the metal gate including titanium nitride and the metal contact region including a tungsten silicide region on and contacting the metal gate and a tungsten region on the tungsten silicide region.

An example memory device 5 can include features of any of the preceding example memory devices and can include the metal gate or the gate dielectric having a material that acts as a work function shifter.

An example memory device 6 can include features of any of the preceding example memory devices and can include the transistor being a n-channel metal oxide semiconductor transistor and the gate stack having an effective work function of 4.4 eV or less.

An example memory device 7 can include features of any of the preceding example memory devices and can include the transistor being a p-channel metal oxide semiconductor transistor and the gate stack having an effective work function of 4.85 eV or less.

An example memory device 8 can include features of any of the preceding example memory devices and can include the metal gate being a conditioned metal gate resulting from depositing polysilicon on the metal gate, annealing the polysilicon and metal gate, and removing the polysilicon to achieve a desired effective work function.

In an example memory device 9, any of the memory devices of example memory devices 1 to 8 may include memory devices incorporated into an electronic apparatus further comprising a host processor or memory controller and a communication bus extending between the host processor/memory controller and the memory device.

In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be operated in accordance with any of the below example methods 1 to 11 and methods 12 to 16.

An example method 1 of forming a memory device can comprise forming a memory array region and forming a transistor in a periphery to the memory array region. Forming the transistor can include forming a gate dielectric on a channel structure in a substrate and forming a set of one or more metals on and contacting the gate dielectric, forming a gate stack. The gate stack can include a metal gate with a metal contact region on and contacting the metal gate, where the metal gate can include material diffused into the metal gate and the gate stack can be structured without a polysilicon region.

An example method 2 of forming a memory device can include features of example method 1 of forming a memory device and can include forming the gate dielectric to include forming a high-k dielectric material on an ILD, with the ILD on and contacting the channel structure and the high-k dielectric material contacting the metal gate.

An example method 3 of forming a memory device can include features of any of the preceding example methods of forming a memory device and can include forming the metal gate to include forming titanium nitride.

An example method 4 of forming a memory device can include features of any of the preceding example methods of forming a memory device and can include conditioning the metal gate by depositing polysilicon on the metal gate, annealing the polysilicon and metal gate at a threshold temperature range to achieve a selected effective work function for the gate stack, and removing the polysilicon.

An example method 5 of forming a memory device can include features of example method 4 of forming a memory device and any of the preceding example methods of forming a memory device and can include the threshold temperature range to include a temperature spike above 800° C.

In an example method 6, any of the example methods 1 to 5 of forming a memory device may be performed in forming an electronic apparatus further comprising a host processor and a communication bus extending between the host processor and a memory system.

In an example method 7 of forming a memory device, any of the example methods 1 to 6 of forming a memory device may be modified to include operations set forth in any other of example methods 1 to 6.

In an example method 8 of forming a memory device, any of the example methods 1 to 7 of forming a memory device may be implemented at least in part through use of instructions stored as a physical state in one or more machine-readable storage devices.

An example method 9 of forming a memory device can include features of any of the preceding example methods 1 to 8 of forming a memory device and can include performing functions associated with any features of example memory devices 1 to 12.

An example method 10 of forming a memory device can comprise forming a HKMG on and contacting a channel structure in a substrate, with the HKMG formed for a transistor in a periphery to a memory array region, the HKMG having a top surface; forming a polysilicon region covering the top surface of the HKMG; annealing the polysilicon region; removing the polysilicon region, exposing the HKMG; and forming a gate stack by forming a metal contact region on the HKMG, with the gate stack structured without a layer of polysilicon in the gate stack.

An example method 11 of forming a memory device can include features of example method 10 of forming a memory device and can include forming the HKMG on and contacting an ILD positioned over memory cells in the memory array region while forming the HKMG for the transistor in the periphery to the memory array region; and forming the polysilicon region covering the HKMG on the ILD in the memory array region while forming the polysilicon region covering the top surface of the HKMG in the periphery.

An example method 12 of forming a memory device can include features of example method 11 of forming a memory device and any of the preceding example method 10 of forming a memory device and can include forming a oxide on the polysilicon region in the memory array region and the periphery; selectively removing the oxide, polysilicon, and the HKMG from the memory array region, while substantially maintaining the oxide, the polysilicon region, and the HKMG in the periphery; and forming a contact to a memory cell while maintaining the polysilicon region above the HKMG.

An example method 13 of forming a memory device can include features of any of the preceding example methods of forming a memory device and can include forming, after removing the polysilicon region from the high-k metal gate in the periphery, the metal contact region on the contact and on the interlayer dielectric in the memory array region while forming the metal contact region on the high-k metal gate for the transistor in the periphery.

An example method 14 of forming a memory device can include features of example method 13 of forming a memory device and any of the preceding example methods 10 to 13 of forming a memory device and can include forming the metal contact region to include: forming a tungsten silicide region on and contacting the HKMG; and forming a tungsten region on the tungsten silicide region.

An example method 15 of forming a memory device can include features of any of the preceding example methods of forming a memory device and can include annealing the polysilicon to include annealing at a threshold temperature range to achieve a selected effective work function for the gate stack.

An example method 16 of forming a memory device can include features of example method 15 of forming a memory device and any of the preceding example methods 11 to 15 of forming a memory device and can include the threshold temperature range to include a temperature spike above 800° C.

In an example method 17 of forming a memory device, any of the example methods 10 to 17 of forming a memory device may be performed in forming an electronic apparatus further comprising a host processor and a communication bus extending between the host processor and a memory system.

In an example method 18 of forming a memory device, any of the example methods 10 to 17 of forming a memory device may be modified to include operations set forth in any other of example methods 10 to 17 of forming a memory device.

In an example method 19 of forming a memory device, any of the example methods 10 to 18 of forming a memory device may be implemented at least in part through use of instructions stored as a physical state in one or more machine-readable storage devices.

An example method 20 of forming a memory device can include features of any of the preceding example methods 10 to 19 of forming a memory device and can include performing functions associated with any features of example memory devices 1 to 12.

An example machine-readable storage device storing instructions, that when executed by one or more processors, cause a machine to perform operations, can comprise instructions to perform functions associated with any features of example memory devices 1 to 12 or perform form methods associated with any features of example methods 1 to 9 of forming a memory device or example methods 10 to 20 of forming a memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a memory array region;
a transistor in a periphery to the memory array region, the transistor including:
a gate dielectric on a channel structure in a substrate; and
a set of metals on and contacting the gate dielectric, forming a gate stack, the gate stack including a metal gate with a metal contact region on and contacting the metal gate, the gate stack structured without a polysilicon region, the metal gate or the gate dielectric including material diffused into the metal gate and/or the gate dielectric.

2. The memory device of claim 1, wherein the gate dielectric includes a high-k dielectric material.

3. The memory device of claim 2, wherein the gate dielectric includes a silicon oxide region or a nitridized silicon oxide region between and contacting the gate stack and the channel structure.

4. The memory device of claim 1, wherein the metal gate includes titanium nitride and the metal contact region includes a tungsten silicide region on and contacting the metal gate, and a tungsten region on the tungsten silicide region.

5. The memory device of claim 1, wherein the metal gate or the gate dielectric includes a material that acts as a work function shifter.

6. The memory device of claim 1, wherein the transistor is a n-channel metal oxide semiconductor transistor and the gate stack has an effective work function of 4.4 eV or less.

7. The memory device of claim 1, wherein the transistor is a p-channel metal oxide semiconductor transistor and the gate stack has an effective work function of 4.85 eV or less.

8. The memory device of claim 1, wherein the metal gate is a conditioned metal gate resulting from depositing polysilicon on the metal gate, annealing the polysilicon and metal gate, and removing the polysilicon to achieve a desired effective work function.

9. A method of forming a memory device, the method comprising:
forming a memory array region;
forming a transistor in a periphery to the memory array region, including:
forming a gate dielectric on a channel structure in a substrate; and
forming a set of one or more metals on and contacting the gate dielectric, forming a gate stack including a metal gate with a metal contact region on and contacting the metal gate, the metal gate including material diffused into the metal gate, the gate stack structured without a polysilicon region.

10. The method of claim 9, wherein forming the gate dielectric includes forming a high-k dielectric material on an interlayer dielectric, with the interlayer dielectric on and contacting the channel structure and the high-k dielectric material contacting the metal gate.

11. The method of claim 9, wherein forming the metal gate includes forming titanium nitride.

12. The method of claim 9, wherein the method includes conditioning the metal gate by depositing polysilicon on the metal gate, annealing the polysilicon and metal gate at a threshold temperature range to achieve a selected effective work function for the gate stack, and removing the polysilicon.

13. The method of claim 12, wherein the threshold temperature range includes a temperature spike above 800° C.

14. A method of forming a memory device, the method comprising:
forming a high-k metal gate on and contacting a channel structure in a substrate, the high-k metal gate formed for a transistor in a periphery to a memory array region, the high-k metal gate having a top surface;
forming a polysilicon region covering the top surface of the high-k metal gate;
annealing the polysilicon region;
removing the polysilicon region, exposing the high-k metal gate; and
forming a gate stack by forming a metal contact region on the high-k metal gate, the gate stack structured without a layer of polysilicon in the gate stack.

15. The method of claim 14, wherein the method includes:
forming the high-k metal gate on and contacting an interlayer dielectric positioned over memory cells in the memory array region while forming the high-k metal gate for the transistor in the periphery to the memory array region; and
forming the polysilicon region covering the high-k metal gate on the interlayer dielectric in the memory array region while forming the polysilicon region covering the top surface of the high-k metal gate in the periphery.

16. The method of claim 15, wherein the method includes:
forming an oxide on the polysilicon region in the memory array region and the periphery;
selectively removing the oxide, polysilicon, and the high-k metal gate from the memory array region, while substantially maintaining the oxide, the polysilicon region, and the high-k metal gate in the periphery; and
forming a contact to a memory cell while maintaining the polysilicon region above the high-k metal gate.

17. The method of claim 16, wherein the method includes:
forming, after removing the polysilicon region from the high-k metal gate in the periphery, the metal contact region on the contact and on the interlayer dielectric in the memory array region while forming the metal contact region on the high-k metal gate for the transistor in the periphery.

18. The method of claim 17, wherein forming the metal contact region includes:
forming a tungsten silicide region on and contacting the high-k metal gate; and
forming a tungsten region on the tungsten silicide region.

19. The method of claim 14, wherein annealing the polysilicon includes annealing at a threshold temperature range to achieve a selected effective work function for the gate stack.

20. The method of claim 19, wherein the threshold temperature range includes a temperature spike above 800° C.
